(19) United States
(12) Patent Application Publication
(10) Pub. No.: US 2025/0287700 A1
(43) Pub. Date: Sep. 11, 2025

(54) SEMICONDUCTOR DEVICE

(71) Applicant: Renesas Electronics Corporation, Tokyo (JP)

(72) Inventors: Satoshi MAEDA, Tokyo (JP); Yasuyuki MORISHITA, Tokyo (JP); Koki NARITA, Tokyo (JP)

(21) Appl. No.: 18/983,472

(22) Filed: Dec. 17, 2024

(30) Foreign Application Priority Data
Mar. 5, 2024 (JP) 2024-032909

(51) Int. Cl. H10D 89/60; H01L 23/528

(52) U.S. Cl. CPC H10D 89/811; H01L 23/5286

(57) ABSTRACT

A protection cell has a first MISFET group composed of a plurality of first MISFETs and a second MISFET group composed of a plurality of second MISFETs. The first MISFET group and the second MISFET group are provided separately from each other. The first MISFET group is electrically connected to a first power wiring group and a first ground wiring group so as to electrically short-circuit them. The second MISFET group is electrically connected to a second power wiring group and a first ground wiring group so as to electrically short-circuit them. The first MISFET group overlaps with a part of the first power wiring group and a part of the first ground wiring group in a plan view.

### CROSS-REFERENCE TO RELATED APPLICATIONS

The disclosure of Japanese Patent Application No. 2024-032909 filed on Mar. 5, 2024, including the specification, drawings and abstract is incorporated herein by reference in its entirety.

### BACKGROUND

The present invention relates to a semiconductor device, particularly to a semiconductor device equipped with a protection cell for an ESD protection circuit.

In order to protect various circuits formed within a semiconductor device from destruction by electrostatic discharge, a semiconductor device equipped with an ESD (Electro-Static Discharge) protection circuit is employed. The ESD protection circuit comprises, for example, a trigger circuit and a discharge circuit. The trigger circuit includes a detection circuit and an inverter. When the detection circuit detects an ESD current to the power supply wiring, the detection circuit outputs a detection signal to the inverter. The inverter, in response to the detection signal, outputs a drive signal to the gate electrodes of the plurality of MISFETs (Metal Insulator Semiconductor Field Effect Transistor) constituting the discharge circuit. By each MISFET of the discharge circuit being in an on state, the ESD current is discharged from the power supply wiring to the ground wiring.

There are disclosed techniques listed below.
[Patent Document 1] International Publication No. 2016/203648

For example, Patent Document 1 discloses an ESD protection circuit comprising an RC timer as a detection circuit, an inverter, and an n-channel transistor as a discharge circuit. Furthermore, Patent Document 1 discloses arranging an RC timer, an inverter, and an n-channel transistor in sequence along one direction as a planar layout for a protection cell of the ESD protection circuit.

### SUMMARY

The present invention relates to a semiconductor device, particularly to a semiconductor device equipped with a protection cell for an ESD protection circuit.

On the other hand, depending on the type of power source used in the semiconductor device, several types of power supply wiring groups are provided, and accordingly, several types of protection cells with different voltage resistances are provided. By laying out each discharge circuit of the several types of protection cells to overlap with the corresponding power supply wiring groups and ground wiring groups in a plan view, rapid discharge can be achieved. However, providing each of the several types of protection cells independently increases the occupied area of the protection cells in the peripheral area, making it difficult to promote the miniaturization of the semiconductor device. Therefore, it is difficult to promote the miniaturization of the semiconductor device while quickly performing discharge and ensuring the reliability of the semiconductor device.

Other problems and novel features will become apparent from the description of this specification and the accompanying drawings.

The typical ones of the embodiments disclosed in the present application will be briefly described as follows.

In one embodiment, there is provided a core area provided with a first circuit and a second circuit, a peripheral area surrounding the core area in a plan view, a protection cell provided in the peripheral area and constituting an ESD protection circuit, a first power wiring group for supplying a first power supply potential to the first circuit, a second power wiring group for supplying a second power supply potential to the second circuit, a first ground wiring group for supplying a first ground potential to the first circuit and the second circuit, the first power wiring group, the second power wiring group, and the first ground wiring group are provided in the peripheral area so as to overlap with the protection cell in a plan view, the protection cell has a first MISFET group composed of a plurality of first MISFETs and a second MISFET group composed of a plurality of second MISFETs, the first MISFET group and the second MISFET group are provided separately from each other, the first MISFET group is electrically connected to the first power wiring group and the first ground wiring group so as to electrically short-circuit them, the second MISFET group is electrically connected to the second power wiring group and the first ground wiring group so as to electrically short-circuit them, the first MISFET group overlaps with a part of the first power wiring group and a part of the first ground wiring group in a plan view.

According to an embodiment, it is possible to promote miniaturization of a semiconductor device and to ensure the reliability of the semiconductor device.

### BRIEF DESCRIPTION OF THE DRAWINGS

FIG. 1 is a plan view showing a semiconductor device according to the first embodiment.

FIG. 2 is a plan view showing a semiconductor device according to the first embodiment.

FIG. 3 is an equivalent circuit diagram showing an ESD protection circuit in the first embodiment and the examined example.

FIG. 4 is an equivalent circuit diagram showing an ESD protection circuit in the first embodiment and the examined example.

FIG. 5 is a plan view showing a protection cell in the examined example.

FIG. 6 is a plan view showing power supply wiring groups and ground wiring groups formed above the protection cell in the examined example.

FIG. 7 is a plan view for explaining the problems of the examined example.

FIG. 8 is an equivalent circuit diagram for explaining the problems of the examined example.

FIG. 9 is a plan view for explaining other problems of the examined example.

FIG. 10 is a plan view showing a protection cell in the first embodiment.

FIG. 11 is a plan view showing power supply wiring groups and ground wiring groups formed above the protection cell in the first embodiment.

FIG. 12 is a plan view showing a detailed structure of the protection cell in the first embodiment.

FIG. 13 is a cross-sectional view showing a protection cell in the first embodiment.

FIG. 14 is a plan view showing a MISFET in the first embodiment.

FIG. 15 is a cross-sectional view showing a MISFET in the first embodiment.

FIG. 16 is an equivalent circuit diagram showing an ESD protection circuit in the first embodiment.

FIG. 17 is an equivalent circuit diagram showing an ESD protection circuit in the second embodiment.

FIG. 18 is a plan view showing a protection cell in the second embodiment.

FIG. 19 is a plan view showing a detailed layout of the protection cell in the second embodiment.

### DETAILED DESCRIPTION

Hereinafter, embodiments are described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

Furthermore, the X direction, Y direction, and Z direction described in this application intersect each other and are orthogonal to each other. In this application, the Z direction is described as the vertical direction, depth direction, or thickness direction of a certain structure. The expressions “plan view” or “planar view” used in this application mean that the plane constituted by the X direction and Y direction is considered as the “plane,” and viewing this “plane” from the Z direction.

### First Embodiment

### <Semiconductor Device Planar Layout>

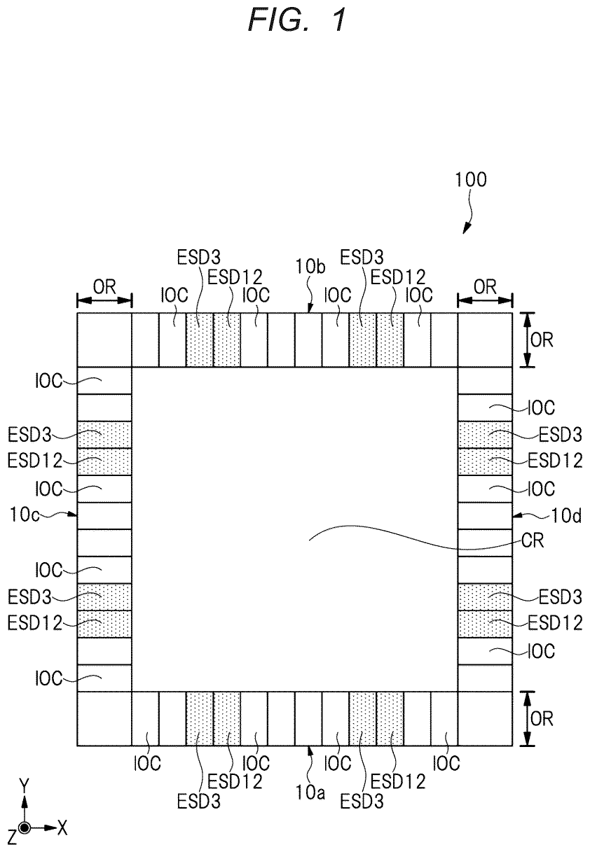

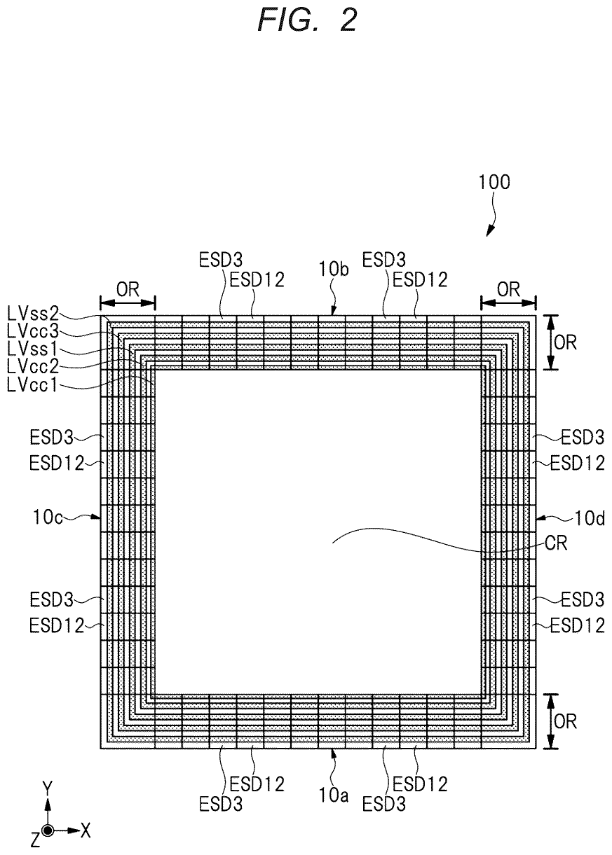

The planar layout of the semiconductor device 100 in the first embodiment will be described below using FIGS. 1 and 2.

As shown in FIG. 1, semiconductor device 100 is a semiconductor chip, comprising a core area CR and a peripheral area OR that surrounds the core area CR in a plan view. The core area CR is equipped with a plurality of circuits. These the plurality of circuits include, for example, logic circuits that constitute a CPU or SRAM, and analog IP (Intellectual Property). IP refers to circuit function blocks with specific roles. Examples of analog IP include Phase Locked Loops (PLL), True Random Number Generators (TRNG), oscillators, temperature sensors, Analog-to-Digital Converters, and Digital-to-Analog Converters, among others.

The logic circuit is composed of low-voltage MISFETs. The analog IP is composed of high-voltage MISFETs having a higher withstand voltage than the low-voltage MISFETs. For example, the thickness of the gate insulating film of the low-voltage MISFET is thinner than that of the high-voltage MISFET, and the gate length of the low-voltage MISFET is shorter than that of the high-voltage MISFET. Furthermore, the pitch between the gate electrodes of a plurality of low-voltage MISFETs is narrower than the pitch between the gate electrodes of a plurality of high-voltage MISFETs.

In the peripheral region OR, a plurality of protection cells ESD12, a plurality of protection cells ESD3, and a plurality of I/O (Input/Output) signal cells IOC are provided. The I/O signal cells IOC are composed of the above mentioned high-voltage MISFETs.

The plurality of protection cells ESD12 and the plurality of protection cells ESD3 each include a plurality of MISFETs for constituting an ESD protection circuit. The protection cell ESD12 constitutes an ESD protection circuit for a plurality of circuits provided in the core region CR. The protection cell ESD3 constitutes an ESD protection circuit for the I/O signal cells IOC.

The planar shape of the semiconductor device 100 is rectangular, and the semiconductor device 100 includes sides 10a and 10b along the X direction, and sides 10c and 10d along the Y direction. Sides 10a, 10b, 10c, and 10d constitute the outer edge of the peripheral region OR. The peripheral region OR is an area provided between the core region CR and sides 10a, 10b, 10c, and 10d.

As shown in FIG. 2, the peripheral region OR is provided with a group of power supply wirings LVcc consisting of a plurality of power supply wirings, and a group of ground wirings LVss consisting of a plurality of ground wirings. The group of power supply wirings LVcc includes a group of power supply wirings LVcc1, a group of power supply wirings LVcc2 for supplying a higher power supply voltage than the group of power supply wirings LVcc1, and a group of power supply wirings LVcc3 for supplying a higher power supply voltage than the group of power supply wirings LVcc2. The group of ground wirings LVss includes a group of ground wirings LVss1 and a group of ground wirings LVss2.

Power supply wiring groups LVcc1, LVcc2, LVcc3, ground wiring groups LVss1, and LVss2 surround the core region CR in a plan view and run along sides 10a, 10b, 10c, and 10d so as to overlap with protection cells ESD12, ESD3, and I/O signal cell IOC in a plan view.

The power supply wiring group LVcc1 supplies a power potential to a plurality of circuits constituted by low-voltage MISFETs in the core region CR. The power supply wiring group LVcc2 supplies a power potential to a plurality of circuits constituted by high-voltage MISFETs in the core region CR. The ground wiring group LVss1 supplies a ground potential to the plurality of circuits constituted by either low-voltage MISFETs or high-voltage MISFETs in the core region CR. The power supply wiring group LVcc3 supplies a power potential to the I/O signal cell IOC. The ground wiring group LVss2 supplies a ground potential to the I/O signal cell IOC.

It should be noted that, as will be described in detail later, the power supply wiring groups LVcc1, LVcc2, LVcc3, and ground wiring groups LVss1, LVss2 are each constituted by a plurality of wirings M13 and M14 formed in the global wiring layer among the multilayer wiring layers.

### <ESD Protection Circuit>

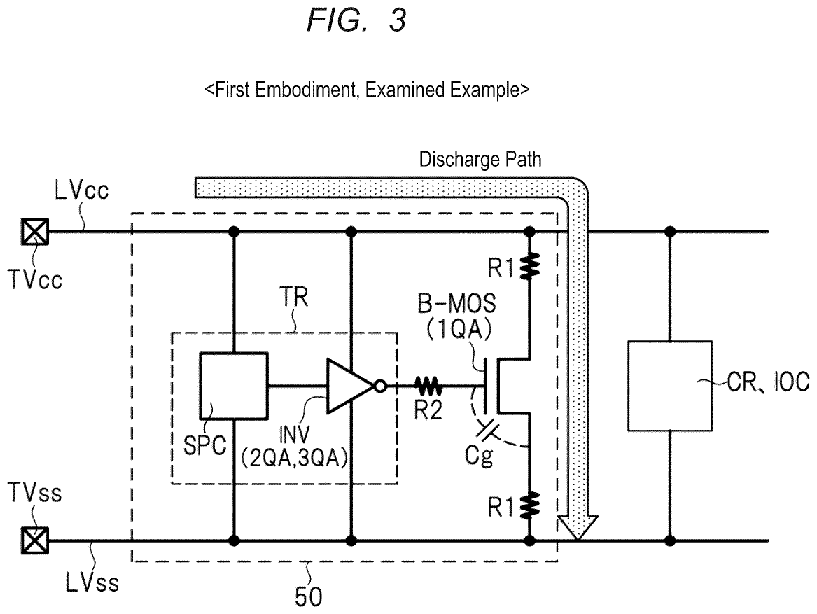

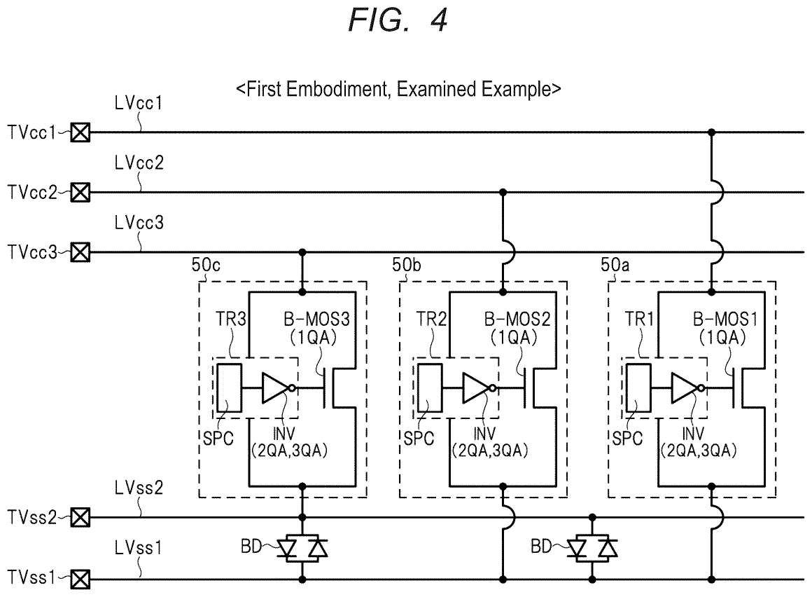

Hereinafter, using FIGS. 3 and 4, a description will be given of an ESD protection circuit 50 provided in a semiconductor device 100 according to the first embodiment.

As shown in FIG. 3, a plurality of circuits in the core region CR and the I/O signal cell IOC are supplied with a power potential from a power terminal TVcc connected to the power supply wiring group LVcc, and a ground potential from a ground terminal TVss connected to the ground wiring group LVss.

The ESD protection circuit 50 includes a trigger circuit TR and a discharge circuit B-MOS. The trigger circuit TR includes a detection circuit SPC and an inverter INV. The discharge circuit B-MOS includes a group of MISFETs 1QA. The group of MISFETs 1QA is constituted by a plurality of n-type MISFETs 1Q connected in parallel. The inverter INV includes groups of MISFETs 2QA and 3QA. The group of MISFETs 2QA is constituted by a plurality of p-type MISFETs 20 connected in parallel. The group of MISFETs 3QA is constituted by a plurality of n-type MISFETs 3Q connected in parallel. The detection circuit SPC is a time constant circuit that detects a positive surge voltage, for example, constituted by an integration circuit including a resistive element and a capacitive element.

The detection circuit SPC, inverter INV (groups of MISFETs 2QA, 3QA), and discharge circuit B-MOS (group of MISFETs 1QA) are electrically connected to the power supply wiring group LVcc and the ground wiring group LVss, respectively, so as to electrically short-circuit them.

When the detection circuit SPC detects an ESD current to the power wiring group LVcc, the detection circuit SPC outputs a detection signal to the inverter INV. The MISFET group 2QA of the inverter INV, in response to the detection signal, outputs a signal to each gate electrode of the plurality of MISFETs 1Q to turn on the plurality of MISFETs 1Q, thereby constituting the discharge circuit B-MOS. As a result, as shown in the “discharge path” of FIG. 3, the ESD current is discharged from the power wiring group LVcc to the ground wiring group LVss.

When the detection circuit SPC does not detect an ESD current, the MISFET group 3QA of the inverter INV outputs a signal to each gate electrode of the plurality of MISFETs 10 to turn off the plurality of MISFETs 1Q.

For example, when a steep high voltage is applied to the power terminal TVcc, the ESD current flows from the power wiring group LVcc to the ground wiring group LVss through the ESD protection circuit 50. This prevents circuits in the core area CR and protected circuits such as I/O signal cells IOC from being destroyed by the steep high voltage.

FIG. 4 shows each ESD protection circuit 50 used in the first embodiment. An ESD protection circuit 50a, which electrically shorts a power supply wiring group LVcc1 and a ground wiring group LVss1, includes a trigger circuit TR1 and a discharge circuit B-MOS1. An ESD protection circuit 50b, which electrically shorts a power supply wiring group LVcc2 and a ground wiring group LVss1, includes a trigger circuit TR2 and a discharge circuit B-MOS2. An ESD protection circuit 50c, which electrically shorts a power supply wiring group LVcc3 and a ground wiring group LVss2, includes a trigger circuit TR3 and a discharge circuit B-MOS3.

A bidirectional diode BD, for example, consists of two diodes where one anode and the other cathode are electrically connected, and the other anode and one cathode are electrically connected. The bidirectional diode BD forms a discharge path from the ground wiring group LVss1 to the ground wiring group LVss2, or from the ground wiring group LVss2 to the ground wiring group LVss1.

Note that each MISFET included in the trigger circuit TR1 and the discharge circuit B-MOS1 is the same as the low-voltage MISFET in the core region CR. Each MISFET included in the trigger circuit TR2 and the discharge circuit B-MOS2 is the same as the high-voltage MISFET in the core region CR. Each MISFET included in the trigger circuit TR3 and the discharge circuit B-MOS3 is the same as the high-voltage MISFET in the I/O signal cell IOC.

### <Examined Example and its Problems>

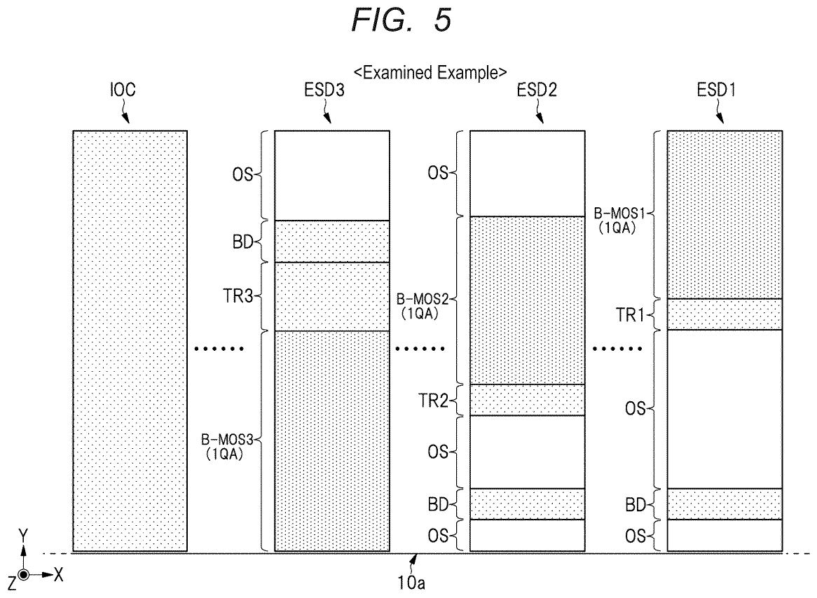

The semiconductor device of the examined example, which the inventors of the present application have examined, will be described below using FIGS. 5 to 9.

FIG. 5 shows a plan layout of protection cells ESD1 for constituting the ESD protection circuit 50a, protection cells ESD2 for constituting the ESD protection circuit 50b, and protection cells ESD3 for constituting the ESD protection circuit 50c. Here, protection cells ESD1, ESD2, and ESD3 arranged alongside 10a are exemplified.

Normally, in the outer peripheral region OR, the width of each of the protection cells ESD1, ESD2, and ESD3 in the Y direction is set to match the width of the I/O signal cell IOC in the Y direction.

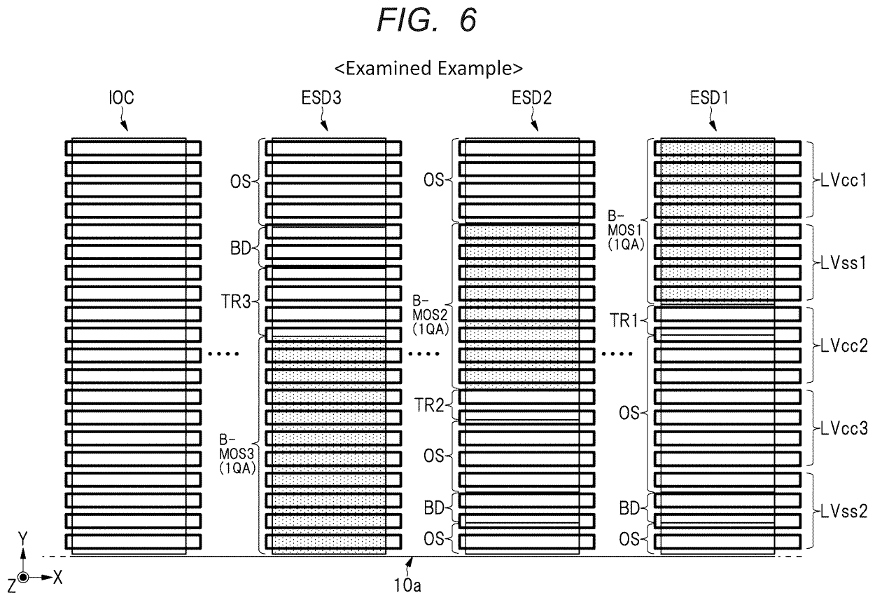

Also, as shown in FIG. 6, to discharge quickly, the discharge circuit B-MOS1 is arranged to overlap as much as possible with the power supply wiring group LVcc1 and the ground wiring group LVss1 in a plan view. For the same reason, the discharge circuit B-MOS2 is arranged to overlap as much as possible with the power supply wiring group LVcc2 and the ground wiring group LVss1 in a plan view, and the discharge circuit B-MOS3 is arranged to overlap as much as possible with the power supply wiring group LVcc3 and the ground wiring group LVss2 in a plan view.

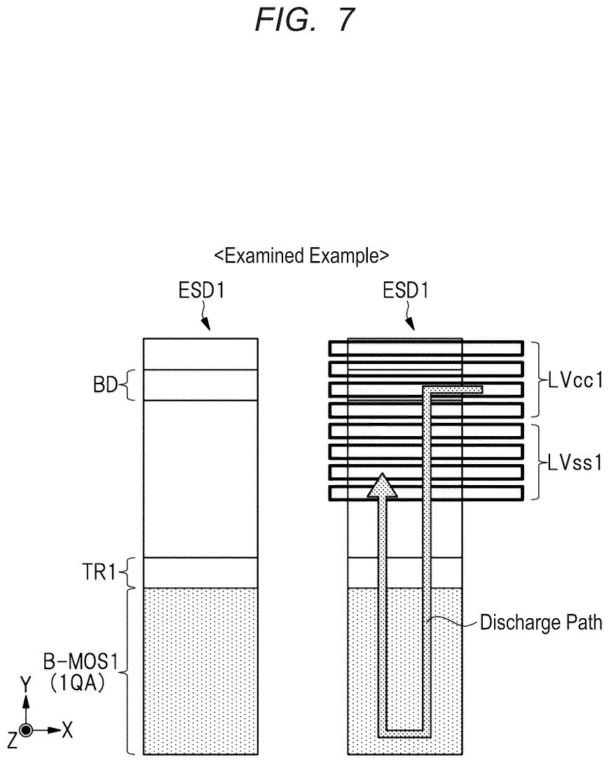

As shown in FIG. 7, for example, in the case of protection cell ESD1, if the discharge circuit B-MOS1 (MISFET group 10A) is provided at a position away from the power supply wiring group LVcc1 and the ground wiring group LVss1, it is necessary to route wiring to connect each MISFET1Q with the power supply wiring group LVcc1 and the ground wiring group LVss1. Therefore, the farther away from the power supply wiring group LVcc1 and the ground wiring group LVss1, the more the wiring resistance (wiring resistance R1 in FIG. 3) increases.

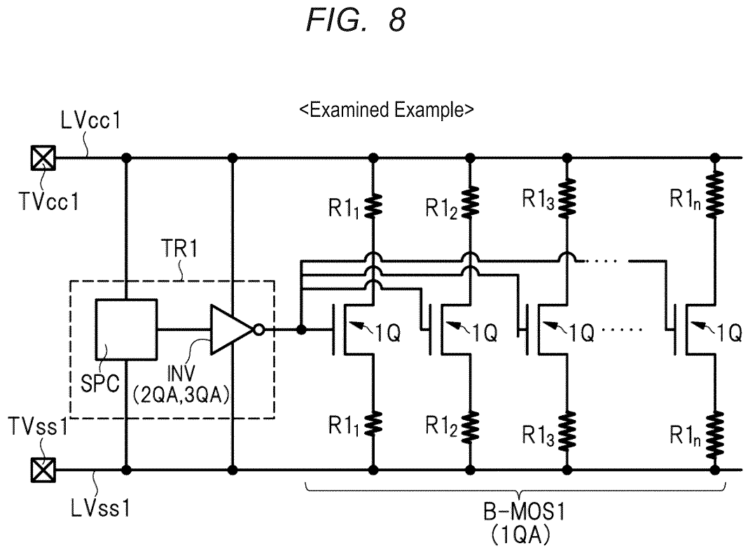

FIG. 8 shows an equivalent circuit diagram of the wiring resistance Rin between the power wiring group LVcc1 and the ground wiring group LVss1, and MISFET1Q. The longer the distance between the power wiring group LVcc1 and the ground wiring group LVss1 and MISFET1Q, that is, the larger the value of the “natural number n”, the greater the wiring resistance Rin increases. Therefore, the longer the distance between the power wiring group LVcc1 and the ground wiring group LVss1 and MISFET1Q, the slower the discharge becomes. That is, the clamp performance of the ESD protection circuit 50 deteriorates.

Meanwhile, as shown in FIG. 5, the protection cells ESD1, ESD2, and ESD3 each have a void OS. In the void OS, semiconductor devices such as MISFETs contributing to the ESD protection circuit 50 are not formed, and dummy gate patterns are formed instead. The dummy gate pattern contributes to, for example, the planarization of the upper surface of the interlayer insulating film formed in the multilayer wiring layer. In the examined example, the reason for providing such a void OS is described below.

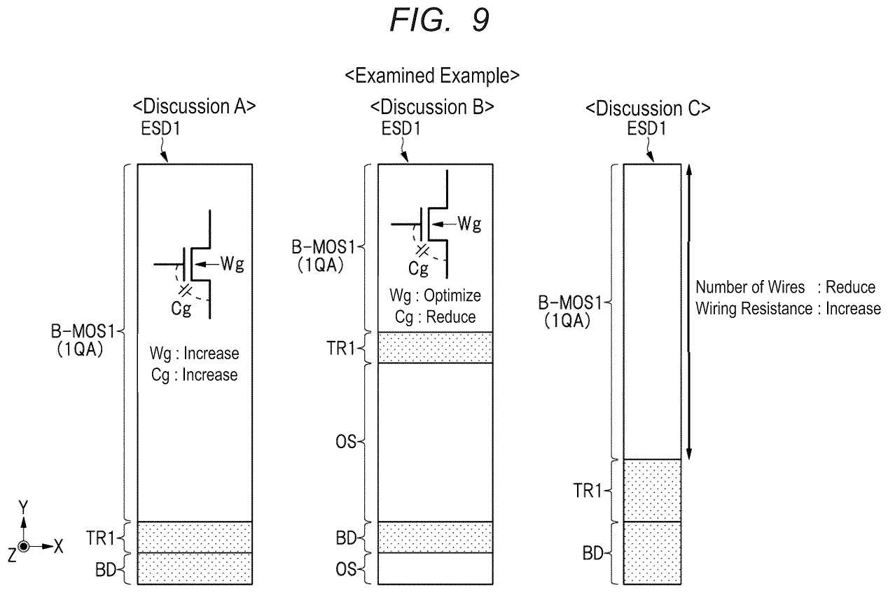

In “Discussion A” of FIG. 9, in order to effectively utilize the open space OS as part of the protection circuit 50, a discharge circuit B-MOS1 (MISFET group 1QA) is also provided in the open space OS.

In recent years, with the miniaturization of semiconductor devices, the application of MISFETs such as the FIN-FET structure has progressed, and the thinning of the gate insulating film of MISFETs and the increase in the gate width of MISFETs have been advancing. Considering the impact of these circumstances on the performance of the ESD protection circuit 50, the problem arises that the gate insulating film of MISFET1Q becomes thinner, and the gate width Wg of MISFET1Q increases, resulting in an excessive increase in gate capacitance Cg.

As in “Discussion A” of FIG. 9, the more the number of MISFET1Q included in the MISFET group 1QA, the more likely it is that the output signal from the trigger circuit TR1 to the MISFET group 1QA will be delayed due to the increase in gate capacitance Cg. Therefore, in MISFET1Q, the driving force of the gate decreases, or the speed of becoming on-state slows down. This leads to the problem that it becomes difficult to sufficiently protect the plurality of circuits provided in the core region CR from ESD current. That is, the clamp performance of the ESD protection circuit 50 decreases.

Therefore, as in “Discussion B” of FIG. 9, in the protection cell ESD1, the number of MISFET1Q included in the MISFET group 1QA is adjusted to optimize the gate width Wg and reduce the gate capacitance Cg. As a result, it becomes necessary to provide the open space OS. For the same reason, open spaces OS are also provided in protection cells ESD2 and ESD3.

However, taking such measures increases the occupied area of protection cells ESD1, ESD2, and ESD3 in the outer peripheral region OR, making it difficult to promote the miniaturization of the semiconductor device 100.

As in “Discussion C” of FIG. 9, it is conceivable to narrow the width of the protection cell ESD1 in the X direction and reduce the area of the protection cell ESD1 to reduce the area of the open space OS. For the same reason, in protection cells ESD2 and ESD3, it is conceivable to narrow the width in the X direction to achieve miniaturization of the semiconductor device 100.

However, taking such measures reduces the number of wires drawn from the power wiring group LVcc1 and the ground wiring group LVss1 in the Y direction. Also, the number of MISFET1Q formed away from the power wiring group LVcc1 and the ground wiring group LVss1 increases, and the length of the above mentioned wires drawn in the Y direction becomes longer. As a result, the wiring resistance R1 increases, and the discharge becomes slower. That is, the clamp performance of the ESD protection circuit 50 decreases. Therefore, narrowing the width of the protection cell ESD1 in the X direction is not very preferable considering the clamp performance of the ESD protection circuit 50.

### Protection Cell of the First Embodiment

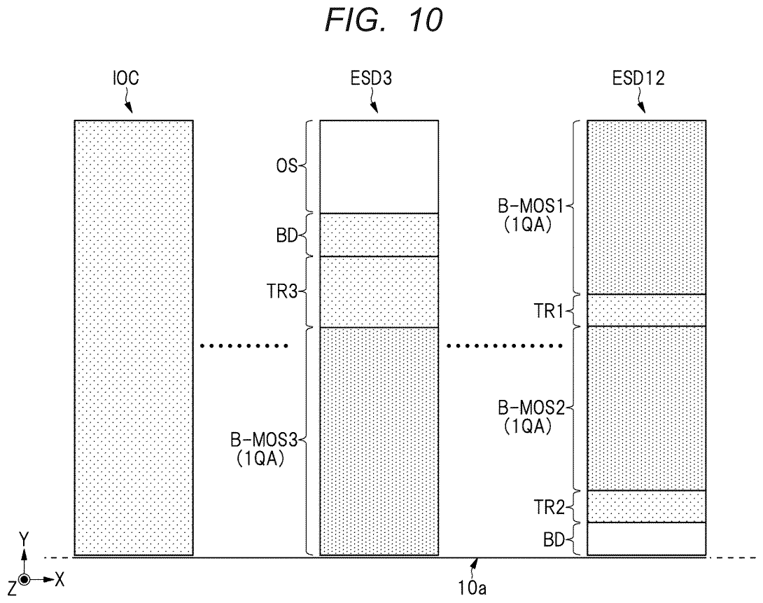

Hereinafter, the protection cell ESD12 in the first embodiment will be described using FIGS. 10 to 15. It should be noted that, herein, the protection cells ESD12 and ESD3 shown in FIG. 1, among which, the protection cells ESD12 and ESD3 arranged along the side 10a, are exemplified.

In the first embodiment, by providing the trigger circuit TR2 and the discharge circuit B-MOS2 of the protection cell ESD2 in the area that was the open space OS in the examined example of the protection cell ESD1 in FIG. 5, the protection cell ESD12 is constituted. That is, the protection cell ESD12 is a cell that integrates the functions of both the protection cell ESD1 and the protection cell ESD2. It should be noted that the protection cell ESD3 and the I/O signal cell IOC of the first embodiment are the same as those of the examined example of the protection cell ESD3 and the I/O signal cell IOC.

As shown in FIG. 10, in the protection cell ESD12, in the direction from the core region CR towards the side 10a, the discharge circuit B-MOS1, the trigger circuit TR1, the discharge circuit B-MOS2, the trigger circuit TR2, and the bidirectional diode BD are provided in sequence.

In other words, the MISFET group 1QA of the discharge circuit B-MOS1 and the MISFET group 1QA of the discharge circuit B-MOS2 are provided apart from each other. The distance between the core region CR and the MISFET group 1QA of the discharge circuit B-MOS1 is shorter than the distance between the core region CR and the MISFET group 1QA of the discharge circuit B-MOS2. The MISFET group 1QA of the discharge circuit B-MOS1 is provided between the core region CR and the trigger circuit TR1. The trigger circuit TR1 is provided between the MISFET group 1QA of the discharge circuit B-MOS1 and the MISFET group 1QA of the discharge circuit B-MOS2. The MISFET group 1QA of the discharge circuit B-MOS2 is provided between the trigger circuit TR1 and the trigger circuit TR2. The trigger circuit TR2 is provided between the MISFET group 1QA of the discharge circuit B-MOS2 and the bidirectional diode BD.

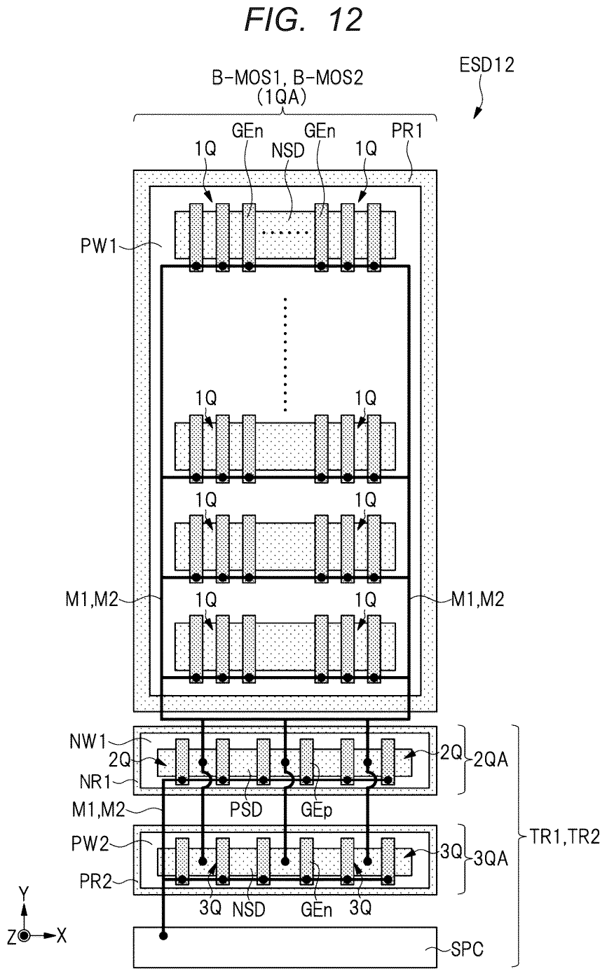

FIG. 12 shows a detailed plan layout of the MISFET groups 1QA, 2QA, 3QA, and the detection circuit SPC included in the protection cell ESD12. The detailed plan layout of the MISFET groups 1QA, 2QA, 3QA, and the detection circuit SPC included in the protection cell ESD3 is obtained by rotating FIG. 12 by 180 degrees.

s shown in FIG. 12, the MISFET group 2QA is provided between the MISFET group 1QA and the MISFET group 3QA. The MISFET group 3QA is provided between the MISFET group 2QA and the detection circuit SPC.

MISFET1Q comprises a p-type well region PW1 formed in a semiconductor substrate, an n-type gate electrode GEn formed on the well region PW1 through a gate insulating film, and an n-type impurity region NSD formed in the well region PW1. The impurity region NSD constitutes the source region or drain region of MISFET1Q. In the well region PW1, a p-type impurity region PR1 is formed. The impurity region PR1 surrounds a plurality of MISFET1Qs in a plan view. The MISFET group 1QA consists of the plurality of MISFET1Qs connected in parallel.

The plan view arrangement shape of the MISFET group 1QA forms a rectangular shape. The MISFET groups 2QA, 3QA, and the detection circuit SPC are provided along the short side of the MISFET group 1QA.

In other words, the plan shape of the well region PW1 where the MISFET group 1QA is formed is rectangular. Further, the area surrounded by the impurity region PR1 in a plan view is the area where the MISFET group 1QA is arranged, and it is rectangular. Therefore, the long side of the MISFET group 1QA can be referred to as the long side of the well region PW1 or the long side of the impurity region PR1, and the short side of the MISFET group 1QA can be referred to as the short side of the well region PW1 or the short side of the impurity region PR1.

MISFET2Q comprises an n-type well region NW1 formed in a semiconductor substrate, a p-type gate electrode GEp formed on the well region NW1 with a gate insulating film, and a p-type impurity region PSD formed in the well region NW1. The impurity region PSD constitutes the source region or drain region of MISFET2Q. An n-type impurity region NR1 is formed in the well region NW1. The impurity region NR1 surrounds a plurality of MISFET2Qs in a plan view. A group of MISFETs 2QA consists of the plurality of MISFET2Qs connected in parallel.

MISFET3Q comprises a p-type well region PW2 formed in a semiconductor substrate, an n-type gate electrode GEn formed on the well region PW2 with a gate insulating film, and an n-type impurity region NSD formed in the well region PW2. The impurity region NSD constitutes the source region or drain region of MISFET3Q. A p-type impurity region PR2 is formed in the well region PW2. The impurity region PR2 surrounds a plurality of MISFET3Qs in a plan view. A group of MISFETs 3QA consists of the plurality of MISFET3Qs connected in parallel.

In the first embodiment, MISFET1Q is of n-type, MISFET2Q is of p-type, and MISFET3Q is of n-type as examples. However, if MISFET1Q is of p-type, p-type MISFET2Q and n-type MISFET3Q are used. In that case, for example, the impurity region NSD becomes a p-type impurity region, and the conductivity type of each component included in the groups of MISFETs 1QA, 2QA, and 3QA becomes the opposite conductivity type.

To connect the groups of MISFETs 1QA, 2QA, 3QA, and the detection circuit SPC, a plurality of wires M1 and a plurality of wires M2 are used. Wire M1 is formed in the lowest wiring layer of the multilayer wiring layers, and wire M2 is formed in the wiring layer above wire M1.

The detection circuit SPC is electrically connected to each gate electrode GEp of a plurality of MISFET2Qs and each gate electrode GEn of a plurality of MISFET3Qs through wires M1 and M2. Each drain region of the plurality of MISFET2Qs and the plurality of MISFET3Qs is electrically connected to each gate electrode GEn of a plurality of MISFET1Qs through wires M1 and M2.

For clarity of the drawings, only wires M1 and M2 are used to connect the groups of MISFETs 1QA, 2QA, 3QA, and the detection circuit SPC are illustrated here.

That is, some of the plurality of wires M1 and the plurality of wires M2 are electrically connected to the power wiring groups LVcc1, LVcc2, or the ground wiring group LVss1 through wires M3 to M12. Therefore, the groups of MISFETs 1QA, 2QA, 3QA, or the detection circuit SPC are electrically connected to the power wiring groups LVcc1, LVcc2, or the ground wiring group LVss1 through wires M1 to M12.

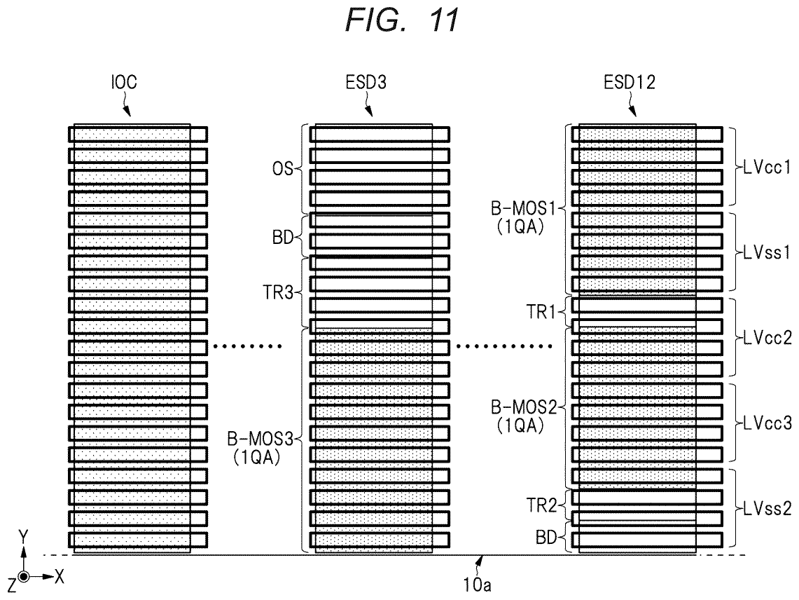

FIG. 11 shows a plan layout of power wiring groups LVcc1, LVcc2, LVcc3, ground wiring groups LVss1, and LVss2 provided above the protection cell ESD12, protection cell ESD3, and I/O signal cell IOC.

In order to discharge quickly, the MISFET group 1QA of the discharge circuit B-MOS1 is arranged to overlap as much as possible with the power wiring group LVcc1 and the ground wiring group LVss1 in a plan view. The MISFET group 1QA of the discharge circuit B-MOS1 overlaps at least a part of the power wiring group LVcc1 and a part of the ground wiring group LVss1 in a plan view.

As described above, in the well region PW1, a plurality of impurity regions NSD, which constitute the source or drain regions of the plurality of MISFETs 10, are formed. Therefore, more preferably, the area of the well region PW1 that overlaps with the power wiring group LVcc1 and the ground wiring group LVss1 in a plan view is larger than the area of the well region PW1 that does not overlap with the power wiring group LVcc1 and the ground wiring group LVss1. Even more preferably, the area of the plurality of impurity regions NSD that overlaps with the power wiring group LVcc1 and the ground wiring group LVss1 in a plan view is larger than the area of the plurality of impurity regions NSD that does not overlap with the power wiring group LVcc1 and the ground wiring group LVss1.

Furthermore, in order to discharge quickly, the MISFET group 1QA of the discharge circuit B-MOS2 is arranged to overlap as much as possible with the power wiring group LVcc2 and the ground wiring group LVss1 in a plan view. In the example of FIG. 11, the MISFET group 2QA overlaps at least a part of the power wiring group LVcc2 in a plan view.

The low-voltage MISFET in the core region CR, which is electrically connected to the power wiring group LVcc1 and the ground wiring group LVss1, has a lower EDS withstand voltage than the high-voltage MISFET in the core region CR, which is electrically connected to the power wiring group LVcc2 and the ground wiring group LVss1. Therefore, the arrangement of the MISFET group 1QA of the discharge circuit B-MOS1 and the MISFET group 1QA of the discharge circuit B-MOS2 is set to prioritize the discharge by the MISFET group 1QA of the discharge circuit B-MOS1 over the discharge by the MISFET group 1QA of the discharge circuit B-MOS2.

Although it is optimal for the MISFET group 1QA of the discharge circuit B-MOS2 to be arranged to overlap both the power wiring group LVcc2 and the ground wiring group LVss1 in a plan view, the high-voltage MISFET in the core region CR, which is electrically connected to the power wiring group LVcc2 and the ground wiring group LVss1, has a relatively high EDS withstand voltage. Therefore, even if the speed of discharge is slightly delayed, the high-voltage MISFET in the core region CR can be protected. In the first embodiment, the protection cell ESD12, the speed of discharge by the MISFET group 1QA of the discharge circuit B-MOS2 is not optimal, but if the MISFET group 1QA of the discharge circuit B-MOS2 is arranged to overlap a part of the power wiring group LVcc2 in a plan view, the speed of discharge is within an acceptable range.

As described above, by using the protection cell ESD12 of the first embodiment, it is possible to suppress the occurrence of open space OS and reduce the occupied area of the protection cell in the outer peripheral region OR, thereby facilitating the miniaturization of the semiconductor device 100. At the same time, it can discharge quickly and ensure the reliability of the semiconductor device 100.

### <Cross-Sectional Structure of the Protection Cell>

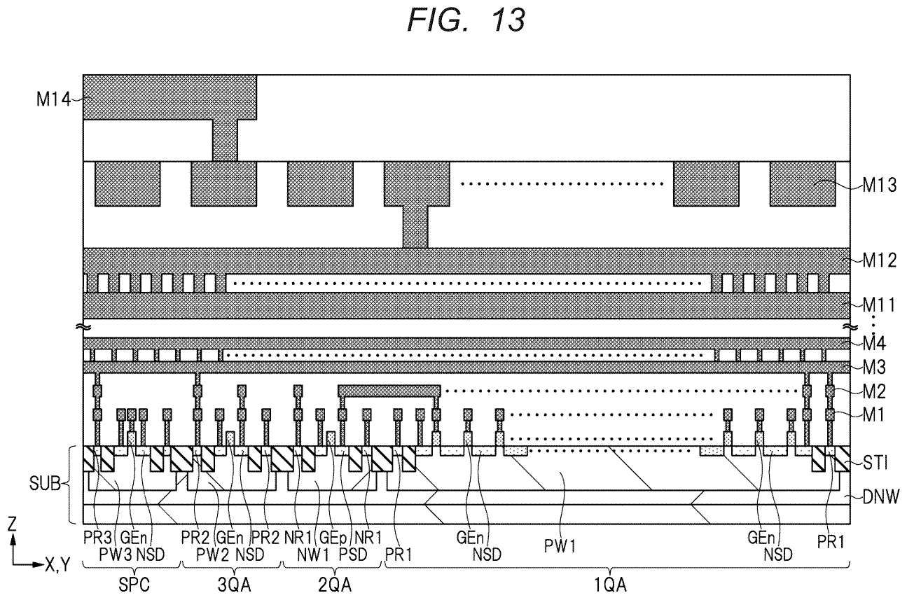

FIG. 13 shows an example of the cross-sectional structure of the MISFET groups 1QA, MISFET groups 2QA, MISFET groups 3QA, and the detection circuit SPC contained in the protection cell ESD12 or protection cell ESD3. It should be noted that FIG. 13 is essentially a cross-sectional view when viewed from the X direction of the surface constituted in the Y direction and Z direction with respect to the plan view of FIG. 12. However, to make the structure of each MISFET easier to understand, in FIG. 13, the arrangement direction of each gate electrode GEn, GEp, and each impurity region NSD, PSD is changed and illustrated.

As shown in FIG. 13, semiconductor device 100 includes a semiconductor substrate SUB, a plurality of transistors, and a multilayer wiring layer formed on the semiconductor substrate SUB.

The semiconductor substrate SUB has an upper surface and a lower surface, and is made of, for example, p-type silicon. In the semiconductor substrate SUB, an element isolation part STI is formed. The element isolation part STI includes a groove formed in the semiconductor substrate SUB to reach a predetermined depth from the upper surface of the semiconductor substrate SUB, and an insulating film embedded in the groove. The insulating film is, for example, a silicon oxide film.

In the semiconductor substrate SUB, an n-type well region DNW is formed. In the well region DNW, a p-type well region PW1, an n-type well region NW1, a p-type well region PW2, and a p-type well region PW3 are formed.

It should be noted that the semiconductor substrate SUB is electrically connected to the ground wiring groups LVss1. The well region DNW serves to electrically isolate the semiconductor substrate SUB and the well regions PW1, PW2, or PW3. As an area for electrically connecting the semiconductor substrate SUB to the ground wiring groups LVss1, for example, when using the protection cell ESD12, it is not necessary for the protection cell ESD12 to have the well region DNW formed.

On the well regions PW1, PW2, and PW3, gate electrodes GEn is formed through gate insulating films, respectively. The gate electrode GEn is, for example, an n-type polycrystalline silicon film. On the well region NW1, a gate electrode GEp is formed through a gate insulating film. The gate electrode GEp is, for example, a p-type polycrystalline silicon film.

In the well regions PW1, PW2, and PW3, n-type impurity regions NSD are formed, respectively. Also, in the well region PW1, a p-type impurity region PR1 is formed, in the well region PW2, a p-type impurity region PR2 is formed, and in the well region PW3, a p-type impurity region PR3 is formed. In the well region NW1, a p-type impurity region PSD is formed. Also, in the well region NW1, an n-type impurity region NR1 is formed.

The impurity region NSD formed in the well region PW1 functions as a source region or a drain region of MISFET1Q. The portion of the well region PW1 that is located between the source region and the drain region and is covered by the gate electrode GEn functions as the channel region of MISFET1Q.

In the case of the protection cell ESD12, the well region PW1 is electrically connected to the ground wiring group LVss1 through the impurity region PR1. In the case of the protection cell ESD3, the well region PW1 is electrically connected to the ground wiring group LVss2 through the impurity region PR1.

The impurity region PSD formed in the well region NW1 functions as a source region or a drain region of the MISFET2Q. Within the well region NW1, the portion located between the source region and the drain region and covered by the gate electrode GEp functions as the channel region of the MISFET2Q.

In the case of the trigger circuit TR1 of the protection cell ESD12, the well region NW1 is electrically connected to the power wiring group LVcc1 through the impurity region NR1. In the case of the trigger circuit TR2 of the protection cell ESD12, the well region NW1 is electrically connected to the power wiring group LVss2 through the impurity region NR1. In the case of the protection cell ESD3, the well region NW1 is electrically connected to the power wiring group LVss3 through the impurity region NR1.

The impurity region NSD formed in the well region PW2 functions as a source or drain region of the MISFET3Q. In the well region PW2, the area located between the source and drain regions and covered by the gate electrode GEn functions as the channel region of the MISFET3Q.

In the case of the protection cell ESD12, the well region PW2 is electrically connected to the ground wiring group LVss1 through the impurity region PR2. In the case of the protection cell ESD3, the well region PW2 is electrically connected to the ground wiring group LVss2 through the impurity region PR2.

The integration circuit of the detection circuit SPC is mainly composed of capacitive elements and resistive elements. These capacitive elements and resistive elements can be configured by appropriately combining the well region PW3, the gate insulating film formed on the well region PW3 and the gate electrode GEn, and the impurity region NSD formed in the well region PW3. The resistive elements may be composed of a barrier metal film included in the wiring with a damascene structure or dual damascene structure described later.

The multilayer wiring layer is formed on the semiconductor substrate SUB and has a plurality of wiring layers. In the example of FIG. 13, the multilayer wiring layer is composed of the first wiring layer to the fourteenth wiring layer. In each of the first to fourteenth wiring layers, wirings M1 to M14 are formed, respectively. The first to fifth wiring layers are local wiring layers, the sixth to twelfth wiring layers are semi-global wiring layers, and the thirteenth and fourteenth wiring layers are global wiring layers.

The thickness of each of the wirings M13 and M14 is thicker than that of each of the wirings M6 to M12, and the line width of each of the wirings M13 and M14 is wider than that of each of the wirings M6 to M12. The thickness of each of the wirings M6 to M12 is thicker than that of each of the wirings M1 to M5, and the line width of each of the wirings M6 to M12 is wider than that of each of the wirings M1 to M5.

Each of the wirings M1 to M14 is a wiring with a damascene structure or dual damascene structure, for example, composed of a barrier metal film including a tantalum film and a nitride tantalum film, and a copper film formed on the barrier metal film and having a thickness greater than that of the barrier metal film.

In the first embodiment, although the multilayer wiring layer is exemplified as being composed of the first to fourteenth wiring layers, the number of wiring layers in the multilayer wiring layer is not limited to 14 and may be more or less than 14.

Note that the power terminals TVcc, TVcc1, TVcc2, TVcc3, and the ground terminals TVss, TVss1, TVss2 are constituted by a part of the wiring formed on the upper layer of the wiring M14 (not shown). The wiring formed on the upper layer of wiring M14 is primarily formed of a patterned aluminum alloy film.

### <Detailed Structure of Each MISFET>

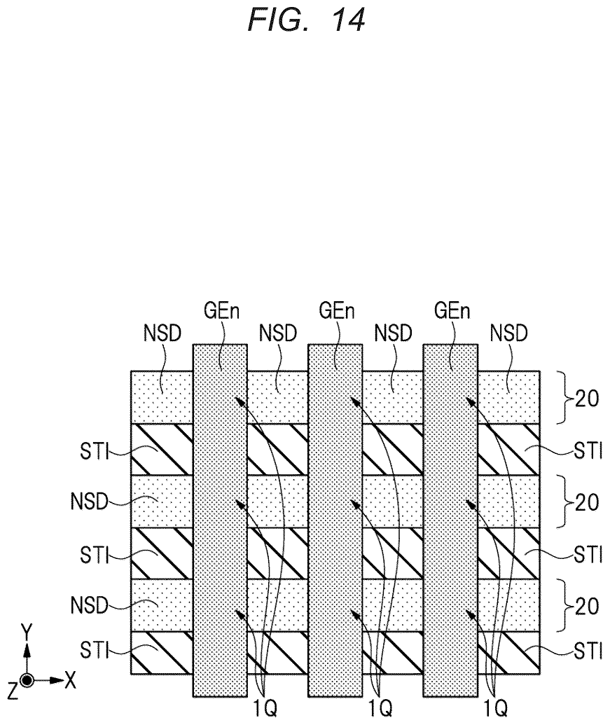

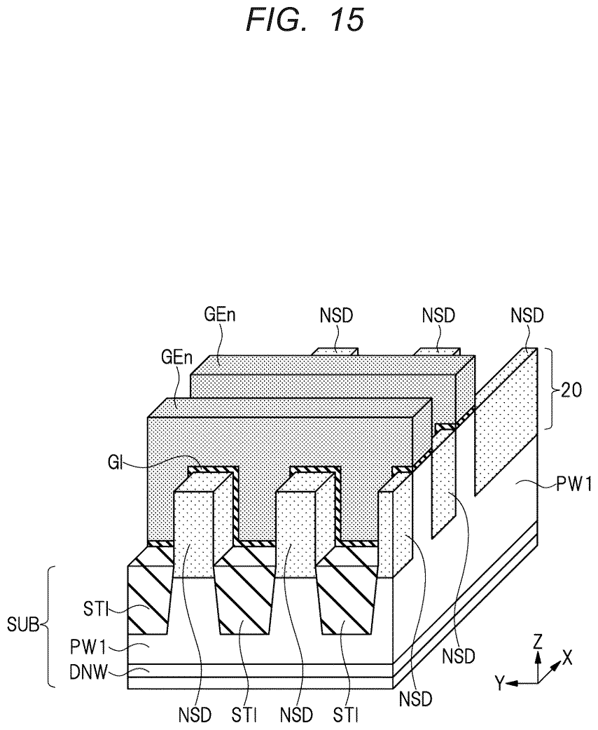

Hereinafter, with reference to FIGS. 14 and 15, the detailed structure of a plurality of MISFETs included in the semiconductor device 100, such as MISFET1Q, MISFET2Q, MISFET3Q, low-voltage MISFETs provided in the core region CR, and high-voltage MISFETs provided in both the core region CR and the I/O signal cell IOC, will be described.

In the first embodiment, the channel region of each of the plurality of MISFETs included in semiconductor device 100 is three-dimensionally covered by the gate electrode of each of the plurality of MISFETs. Such MISFETs may employ a FIN-FET structure, or a GAA (Gate All Around) structure using nanowires or nanosheets.

In this section, an explanation is provided for the case where a plurality of MISFETs included in the semiconductor device 100 have a FIN-FET structure. In FIGS. 14 and 15, a plurality of MISFETs 10 included in the MISFET group 1QA are exemplified.

As illustrated in FIGS. 14 and 15, a semiconductor substrate SUB is provided with a plurality of protrusions 20, which are part of the semiconductor substrate SUB. The plurality of protrusions 20 extend in the X direction and are spaced apart from each other in the Y direction. On the semiconductor substrate SUB located between the plurality of protrusions 20, an element isolation region STI is formed, respectively. In other words, the space between the plurality of protrusions 20 corresponds to a groove formed in the semiconductor substrate SUB, and inside this groove, the element isolation region STI is formed. The upper surface position of the element isolation region STI is lower than the upper surface position of the protrusions 20.

Gate electrode GEn is formed to extend in the Y direction and to cover the upper surface and both side surfaces of at least one of the plurality of protrusions 20. Gate insulating film GI is formed between the gate electrode GEn and the protrusion 20. Well region PW1 is formed in the semiconductor substrate SUB including the protrusion 20. Impurity region NSD is formed in protrusion 20 (in the well region PW1) exposed from the gate electrode GEn.

In the case of a FIN-FET structure, a well region PW1, which is located between two impurity regions NSD that become the source region or the drain region, and is covered by a gate electrode GEn, becomes the channel region of the MISFET1Q.

In a three-dimensional structure MISFET, compared to a planar structure MISFET, more MISFETs can be arranged in the same planar area, and the gate width Wg per MISFET can be increased in the same planar area. Therefore, in a three-dimensional structure MISFET, compared to a planar structure MISFET, a larger driving current can be secured, and the miniaturization of the semiconductor device 100 can be promoted.

For the purpose of accelerating the speed of MISFETs, the thinning of the gate insulating film GI is being promoted. In the case of low-voltage MISFETs used in the discharge circuit B-MOS1, trigger circuit TR1, and core region CR, the thickness of the gate insulating film GI is, for example, not less than 1 nm and not more than 4 nm. In the case of high-voltage MISFETs used in the discharge circuit B-MOS2, discharge circuit B-MOS3, trigger circuit TR2, trigger circuit TR3, core region CR, and I/O signal cell IOC, the thickness of the gate insulating film GI is thicker than that of the gate insulating film GI of the low-voltage MISFETs, for example, not less than 3 nm and not more than 6 nm.

Furthermore, the gate insulating film GI may be, for example, a silicon oxide film, or a laminated film of a silicon oxide film and a high dielectric constant film. The aforementioned high dielectric constant film is an insulating film having a higher dielectric constant than a silicon nitride film, and is, for example, a hafnium oxide film (HfO2 film) or a hafnium silicate film (HfSiO film).

With the thinning and higher dielectric constant of the gate insulating film GI and the increase in gate width Wg due to the three-dimensional structure, the gate capacitance Cg tends to increase further. However, even when the gate capacitance Cg increases in this way, by using the protection cell ESD12 of the first embodiment, it is possible to reduce the occupied area of the protection cell in the outer peripheral region OR and promote the miniaturization of the semiconductor device 100. At the same time, it is possible to discharge quickly and ensure the reliability of the semiconductor device 100.

As described above, the first embodiment has been explained in the case where the plurality of MISFETS included in the semiconductor device 100 have a three-dimensional structure such as a FIN-FET structure. However, even if the plurality of MISFETs have a planar structure, the protection cell ESD12 of the first embodiment can be effectively utilized.

### Second Embodiment

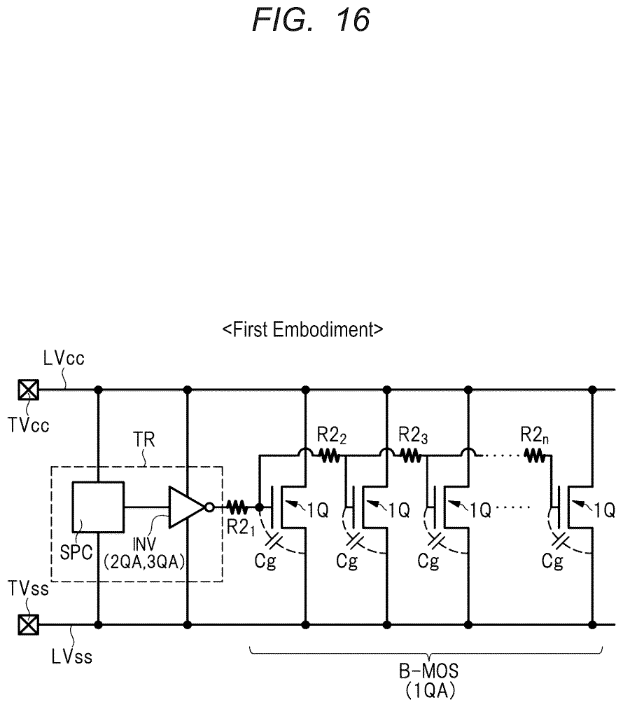

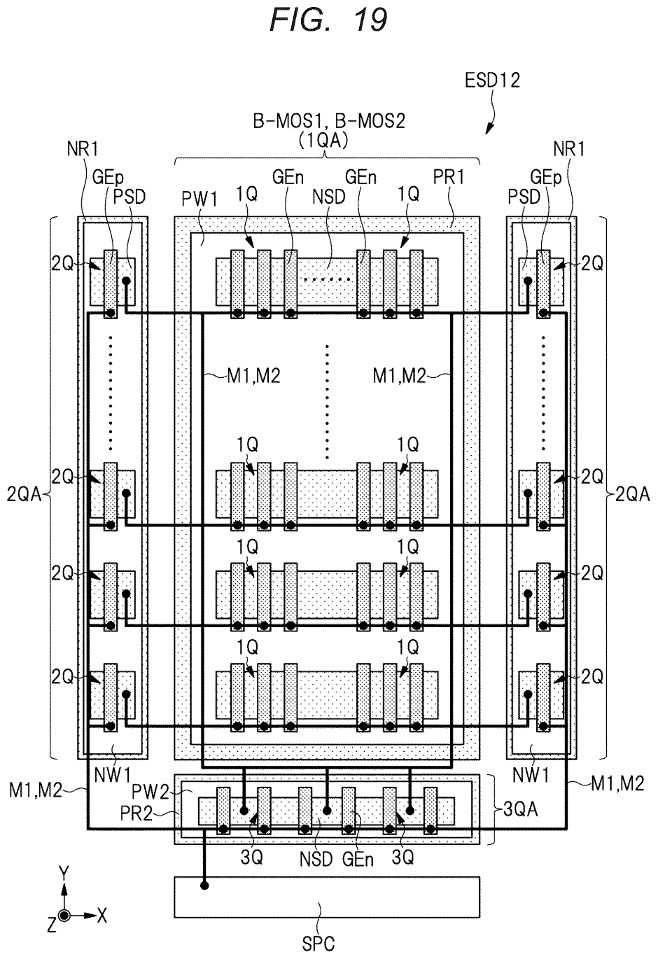

Hereinafter, semiconductor device 100 in the second embodiment will be described using FIGS. 16 and 19. Note that in the following description, mainly the differences from the first embodiment will be explained, and the points overlapping with the first embodiment will be omitted.

In the second embodiment, the planar layout of the protection cell ESD12 and the protection cell ESD3 is changed with the aim of reducing the wiring resistance R2 shown in FIG. 3.

With the miniaturization of semiconductor devices, the thinning and narrowing of wiring are progressing. In particular, in the wiring layers close to the MISFETs, such as wiring M1 and wiring M2, thinning and narrowing are necessary to cope with the miniaturization of the MISFETs, resulting in increased wiring resistance.

As described above, during the discharge of the ESD current, the MISFET group 2QA outputs signals to each gate electrode of the plurality of MISFETs 10 to turn on the plurality of MISFETs 1Q. However, as the thinning and narrowing of wiring M1 and wiring M2 progress, the increase in wiring resistance tends to cause delays in the output signals from the MISFET group 2QA. FIG. 16 shows the equivalent circuit diagram in the case of the planar layout of the protection cell ESD12 shown in FIG. 12. As shown in FIG. 16, in the first embodiment, the farther the distance from the MISFET group 2QA, the more the wiring resistance is added, resulting in greater signal delay. That is, the farther the distance from the MISFET group 2QA, the greater the wiring resistance ΣR2n (n is a natural number) becomes. As the thinning and narrowing of wiring M1 and wiring M2 progress, the increase in wiring resistance ΣR2n becomes even more pronounced.

Therefore, among the plurality of MISFETs 10, those MISFETs 1Q that are farther from the MISFET group 2QA experience a reduction in gate driving force or a slower speed to turn on. In the second embodiment, to achieve quicker discharge, the increase in wiring resistance ΣR2n is improved.

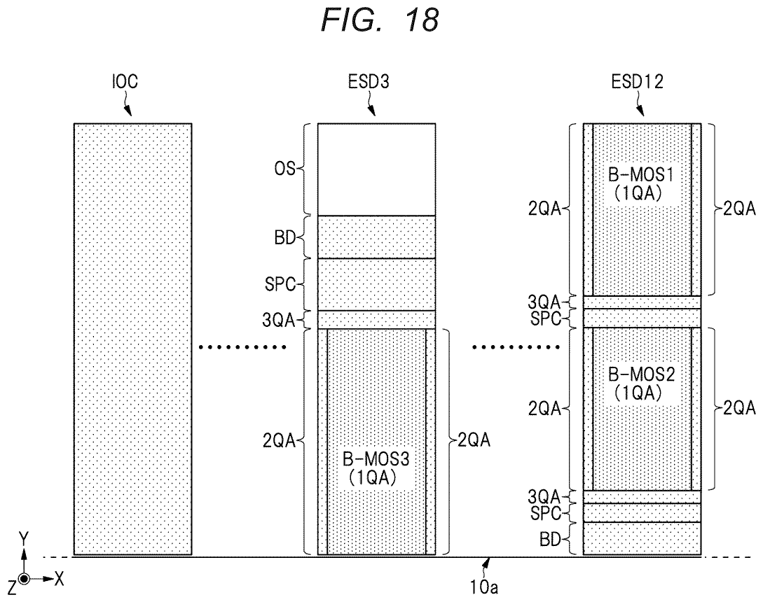

Hereinafter, the protection cell ESD12 and the protection cell ESD3 in the second embodiment will be described using FIGS. 18 and 19.

FIG. 18 shows the planar layout of the protection cell ESD12, the protection cell ESD3, and the I/O signal cell IOC in the second embodiment. FIG. 19 shows a detailed plan layout of the MISFET groups 1QA, MISFET groups 2QA, MISFET groups 3QA, and detection circuit SPC included in the protection cell ESD12. It should be noted that the detailed plan layout of the MISFET groups 1QA, MISFET groups 2QA, MISFET groups 3QA, and detection circuit SPC included in the protection cell ESD3 is obtained by rotating FIG. 19 by 180 degrees.

As shown in FIGS. 18 and 19, in the second embodiment, the position where the MISFET groups 2QA are provided differs from that in the first embodiment. In the second embodiment, the protection cells ESD12 and ESD3 have a pair of MISFET groups 2QA. The MISFET groups 1QA are adjacent to the pair of MISFET groups 2QA and are provided between the pair of MISFET groups 2QA.

Even in the second embodiment, the planar arrangement shape of the MISFET groups 1QA forms a rectangular shape. The pair of MISFET groups 2QA are provided along the long sides of the MISFET groups 1QA, sandwiching the MISFET groups 1QA. The MISFET groups 3QA are provided along the short sides of the MISFET groups 1QA. The detection circuit SPC is provided along the short sides of the MISFET groups 1QA, via the MISFET groups 3QA.

In the first embodiment, as shown in FIG. 16, there was a problem that the wiring resistance ΣR2n increases as the distance from the MISFET groups 2QA increases, resulting in a larger signal delay. For example, as shown in FIG. 12, the wiring path of the MISFET1Q, which is the farthest from the MISFET groups 2QA, is approximately the sum of the length of the long side of the MISFET groups 1QA and half the length of the short side of the MISFET groups 1QA.

In the second embodiment, as shown in FIG. 19, the MISFET groups 2QA are provided along the long sides of the MISFET groups 1QA. Therefore, the wiring path of the MISFET1Q, which is the farthest from the MISFET groups 2QA, is approximately half the length of the short side of the MISFET groups 1QA.

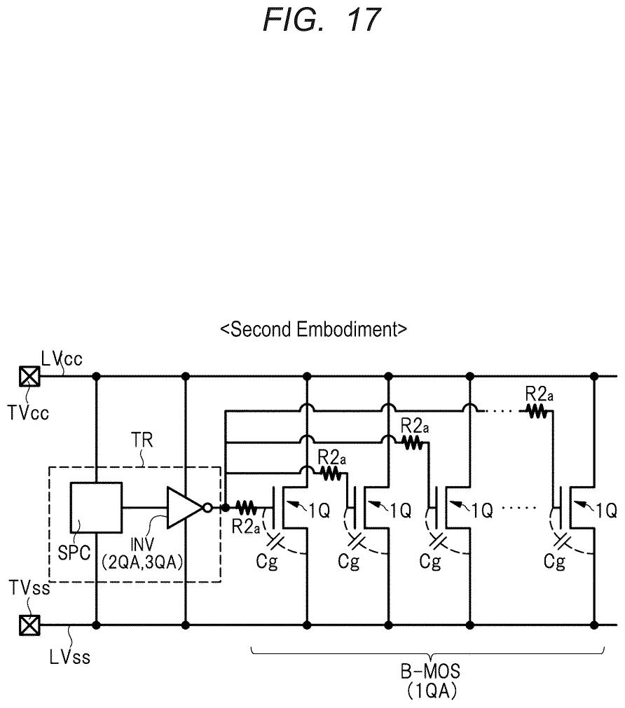

As can be understood by comparing FIGS. 16 and 17, in the first and second embodiments, the distribution of the wiring resistance differs. In the second embodiment, the wiring resistance between each of the gate electrodes GEn of the plurality of MISFET1Qs, which are connected in parallel to each other, and the MISFET groups 2QA is equalized to a relatively low value (wiring resistance R2a). Therefore, in the second embodiment, compared to the first embodiment, the signal delay from the MISFET groups 2QA to the gate electrodes GEn of the MISFET1Q can be significantly suppressed.

Thus, according to the second embodiment, it is possible to suppress the problem of reduced gate driving force in some of the MISFET1Qs of the MISFET groups 10A, and the problem of slower transition to the on-state. Consequently, the clamp performance of the ESD protection circuit 50 can be improved, and the plurality of circuits and I/O signal cells IOC provided in the core region CR can be sufficiently protected from ESD currents. This means that the ESD withstand voltage of the semiconductor device 100 can be improved.

In the second embodiment, the wiring resistance R2 between the MISFET group 2QA of the inverter INV and the discharge circuit B-MOS (MISFET group 1QA) is reduced, but the wiring resistance between the detection circuit SPC and the MISFET group 2QA of the inverter INV slightly increases. However, the number of MISFET2Q included in the MISFET group 2QA is very small compared to the number of MISFET1Q included in the MISFET group 1QA. Furthermore, the total gate width of the plurality of MISFET2Q included in the MISFET group 2QA is about several tens of μm to a hundred μm, which is very small compared to the total gate width of the plurality of MISFET1Q included in the MISFET group 1QA. Therefore, the total gate capacitance of the MISFET group 2QA is small. Hence, the increase in wiring resistance between the detection circuit SPC and the MISFET group 2QA does not significantly affect the clamp performance of the ESD protection circuit 50.

On the other hand, the total gate width of the plurality of MISFET1Q included in the MISFET group 1QA is about several thousand μm, and the total gate capacitance of the MISFET group 1QA is very large compared to the total gate capacitance of the MISFET group 2QA. Therefore, the reduction in wiring resistance between the MISFET group 2QA and the MISFET group 1QA significantly affects the clamp performance of the ESD protection circuit 50. Accordingly, the clamp performance of the ESD protection circuit 50 can be significantly improved by the second embodiment.

As described above, the present invention has been specifically described based on the embodiment, but the present invention is not limited to the above embodiment and can be variously modified without departing from the gist thereof.

What is claimed is:

1. A semiconductor device comprising:
a core area provided with a first circuit and a second circuit;
a peripheral area surrounding the core area in a plan view;
a protection cell provided in the peripheral area and constituting an ESD protection circuit;
a first power wiring group for supplying a first power supply potential to the first circuit;
a second power wiring group for supplying a second power supply potential to the second circuit; and
a first ground wiring group for supplying a first ground potential to the first circuit and the second circuit,
wherein the first power wiring group, the second power wiring group, and the first ground wiring group are provided in the peripheral area so as to overlap with the protection cell in a plan view,
wherein the protection cell has a first MISFET group composed of a plurality of first MISFETs and a second MISFET group composed of a plurality of second MISFETs,
wherein the first MISFET group and the second MISFET group are provided separately from each other,
wherein the first MISFET group is electrically connected to the first power wiring group and the first ground wiring group so as to electrically short-circuit them,
wherein the second MISFET group is electrically connected to the second power wiring group and the first ground wiring group so as to electrically short-circuit them, and
wherein the first MISFET group overlaps with a part of the first power wiring group and a part of the first ground wiring group in a plan view.

2. The semiconductor device according to claim 1, further comprising:
a semiconductor substrate;
a first well region of a first conductivity type formed in the semiconductor substrate; and
a plurality of first impurity regions of a second conductivity type, opposite to the first conductivity type, formed in the first well region and constituting the source or drain regions of the plurality of first MISFETs,
wherein the area of the first well region that overlaps with the first power wiring group and the first ground wiring group in a plan view is larger than the area of the first well region that does not overlap with the first power wiring group and the first ground wiring group.

3. The semiconductor device according to claim 1,
wherein the second MISFET group overlaps with a part of the second power wiring group in a plan view.

4. The semiconductor device according to claim 1,
wherein the second power supply potential is higher than the first power supply potential, and the thickness of each first gate insulating film of the plurality of first MISFETs is thinner than the thickness of each second gate insulating film of the plurality of second MISFETs.

5. The semiconductor device according to claim 1,
wherein the distance between the first MISFET group and the core area is closer than the distance between the second MISFET group and the core area.

6. The semiconductor device according to claim 5
wherein the protection cell further comprises a first trigger circuit,
wherein the first trigger circuit detects an ESD current to the first power wiring group and outputs a signal to each first gate electrode of the plurality of first MISFETs to turn the plurality of first MISFETs on or off, and
wherein the first trigger circuit is provided between the first MISFET group and the second MISFET group.

7. The semiconductor device according to claim 6,
wherein the protection cell further comprises a second trigger circuit,
wherein the second trigger circuit detects an ESD current to the second power wiring group and outputs a signal to each second gate electrode of the plurality of the second MISFETs to turn the plurality of the second MISFETs on or off, and
wherein the second MISFET group is provided between the first trigger circuit and the second trigger circuit.

8. The semiconductor device according to claim 7,
wherein the protection cell further comprises a bidirectional diode electrically connected to the first MISFET group and the second MISFET group via the first ground wiring group, and
wherein the second trigger circuit is provided between the second MISFET group and the bidirectional diode.

9. The semiconductor device according to claim 7, further comprising:
a plurality of first wirings used to connect the first MISFET group and the first trigger circuit, and
a plurality of second wirings used to connect the second MISFET group and the second trigger circuit,
wherein the first power wiring group, the second power wiring group, and the first ground wiring group are formed in a wiring layer above the plurality of first wirings and the plurality of second wirings, and
wherein the thickness of each of the first power wiring group, the second power wiring group, and the first ground wiring group is thicker than the thickness of each of the plurality of first wirings and the plurality of second wirings.

10. The semiconductor device according to claim 5,
wherein the protection cell further comprises a first trigger circuit,
wherein the first trigger circuit includes a first detection circuit, a pair of third MISFET groups constituted by a plurality of third MISFETs, and a fourth MISFET group constituted by a plurality of fourth MISFETS,
wherein the first detection circuit can detect ESD current to the first power wiring group,
wherein the pair of third MISFET groups outputs a signal to each of the first gate electrodes of the plurality of the first MISFETs to turn the plurality of the first MISFETs on, the fourth MISFET group outputs a signal to each of the first gate electrodes of the plurality of the first MISFETs to turn the plurality of the first MISFETs off, the planar arrangement shape of the first MISFET group forms a rectangular shape, the pair of third MISFET groups is provided along the long sides of the first MISFET group, sandwiching the first MISFET group, the fourth MISFET group is provided along the short sides of the first MISFET group, and the first detection circuit is provided along the short sides of the first MISFET group through the fourth MISFET group.

11. The semiconductor device according to claim 10,
wherein the protection cell further comprises a second trigger circuit,
wherein the second trigger circuit includes a second detection circuit, a pair of fifth MISFET groups constituted by a plurality of fifth MISFETs, and a sixth MISFET group constituted by a plurality of sixth MISFETS,
wherein the second detection circuit is capable of detecting an ESD current to the second power wiring group,
wherein the pair of the fifth MISFET groups outputs a signal to each of the second gate electrodes of the plurality of the second MISFETs to turn on the plurality of the second MISFETs,
wherein the sixth MISFET group outputs a signal to each of the second gate electrodes of the plurality of the second MISFETs to turn off the plurality of the second MISFETs,
wherein the planar arrangement shape of the second MISFET group forms a rectangular shape,
wherein the pair of the fifth MISFET groups is provided along the long side of the second MISFET group so as to sandwich the second MISFET group,
wherein the sixth MISFET group is provided along the short side of the second MISFET group, and
wherein the second detection circuit is provided along the short side of the second MISFET group through the sixth MISFET group.

12. The semiconductor device according to claim 1,
wherein each of the first gate electrodes of the plurality of the first MISFETs extends in the first direction in a plan view, and
wherein each of the channel regions of the plurality of the first MISFETs is three-dimensionally covered by each of the first gate electrodes of the plurality of the first MISFETs.

13. The semiconductor device according to claim 12, further comprising:
a semiconductor substrate; and
a plurality of protrusions which are part of the semiconductor substrate, extend in the second direction intersecting the first direction in a plan view, and are separated from each other in the first direction; and
an element isolation part formed on the semiconductor substrate located between the plurality of protrusions,
wherein the position of the upper surface of the element isolation part is lower than the position of the upper surface of the protrusions, and
wherein the first gate electrode is formed to cover at least one of the upper surface and both side surfaces of the plurality of protrusions.

14. The semiconductor device according to claim 1, further comprising;
a first side along the first direction in a plan view;
a second side along the second direction intersecting the first direction in a plan view; and
a plurality of protection cells,
wherein the first side and the second side constitute the outer edge of the outer peripheral region,
wherein the plurality of protection cells include a first protection cell provided between the first side and the core region and a second protection cell provided between the second side and the core region, and
wherein each of the first power wiring group, the second power wiring group, and the first ground wiring group circulates along the first side and the second side in a plan view so as to overlap with the first protection cell and the second protection cell.
